(19) United States
(12) Patent Application Publication
(10) Pub. No.: US 2008/0203388 A1
(43) Pub. Date: Aug. 28, 2008

(54) Apparatus and method for detection of edge damages

(76) Inventors: Jun He, Hillsboro, OR (US); Jeff Hicks, Banks, OR (US); Chris Litteken, Portland, OR (US); Tom Marieb, Portland, OR (US); Alan Lucero, Chandler, AZ (US); Jose Maiz, Portland, OR (US); Jun He, Portland, OR (US); Jeffrey Morisson Hicks, Manning, OR (US)

Correspondence Address: INTEL CORPORATION;c/o INTELLEVATE, LLC, P.O. BOX 52050, MINNEAPOLIS, MN, 55402, US

(21) Appl. No.: 11/712,355

(22) Filed: Feb. 28, 2007

(51) Int. Cl. H01L 23/58; H01L 21/66

(52) U.S. Cl. 257/48; 438/18; 257/E23.179; 257/E21.523; 257/E21.53; 257/E21.531

(57) ABSTRACT

Embodiments of the invention enable detection of edge damages in semiconductor devices. To this purpose, one or more continuity structures may be provided, where each structure comprises an undulating arrangement disposed between active circuits of the semiconductor device and a perimeter of the metallization layers. The continuity structure(s) forms one or more conductive paths intersecting a plurality of metallization layers in the semiconductor device. A relative change in an electrical characteristic of the continuity structure(s) is monitored to ascertain whether or not an edge damage is present.

### BACKGROUND

1. Technical Field

Embodiments of the invention are related to semiconductor devices and in particular to detection of edge damages in such devices.

2. Description of Related Art

Production of integrated circuit (IC) chips typically involves forming circuit elements, such as transistors, on semiconductor wafers which are then diced into individual dies to be packaged into IC chips for their specific applications. Because a series of costly processes is involved in the production of IC chips, reliability of the IC chips is a major concern.

Functionality tests are typically performed on IC chips to isolate malfunctioning chips from functional chips. Failure of chips may be caused by edge damage (e.g. cracks and delamination), transistor shorts, poor plating, overstretching of vias, solder joint fatigue, and electrostatic discharge. Without performing further failure analysis on each malfunctioning IC chip, functionality tests are typically not able to identify the failure mode to determine the causes of failure. Unfortunately, a full failure analysis can be prohibitively slow and expensive which in turn delays failure prevention. For example, conventional techniques to identify edge damages may involve removing the chip packaging for individual visual inspection as well as performing electrical fault isolation and local cross-section failure analysis. These techniques, however, are destructive and time-consuming.

### BRIEF DESCRIPTION OF THE DRAWINGS

FIG. 1 is a partial perspective view of a continuity structure according to one embodiment of the invention.

FIG. 2 is a schematic illustration of a conductive path, including two terminals, according to one embodiment of the invention.

FIGS. 3A to 3C are perspective views of possible arrangements of terminals of a continuity structure in various embodiments of the invention

FIG. 4A is a perspective view of the continuity structure of FIG. 1 when a horizontal crack is propagated there through.

FIG. 4B is a perspective view of the continuity structure of FIG. 1 when a vertical crack is propagated there through.

FIG. 5 is a perspective view of a plurality of continuity structures according to one embodiment of the invention.

FIG. 6 is a flow sequence for detecting edge damage according to one embodiment of the invention.

### DETAILED DESCRIPTION OF ILLUSTRATIVE EMBODIMENTS

In the following description, numerous specific details are set forth in order to provide a thorough understanding of various illustrative embodiments of the present invention. It will be understood, however, to one skilled in the art, that embodiments of the present invention may be practiced without some or all of these specific details. In other instances, well known process operations have not been described in detail in order not to unnecessarily obscure pertinent aspects of embodiments being described. In the drawings, like reference numerals refer to same or similar functionalities or features throughout the several views.

Embodiments of the invention may be implemented in microelectronic devices, including, but not limited to integrated circuit (IC) chips and packaging substrates. The microelectronic devices may include a wafer device or a packaging substrate, having one or more metallization layers arranged in a stacked configuration. The metallization layers may each comprise alternating layers of an electrically conductive material and a dielectric material. The electrically conductive material is patterned to form appropriate active circuits comprising of transistors and other electrical circuit elements, depending on the intended application of the device. Examples of a conductive material include, but not limited to, copper, aluminum, tungsten, nickel and any alloys thereof. Examples of a dielectric material include, but not limited to, epoxy resin, polyimide, silicon dioxide with all its low-k variants and silicon nitride. Via structures or interconnects may be formed in the dielectric materials to conductively couple adjacent conductive materials where required. In an IC chip, metallization layers may be built upon a semiconductor wafer made from a material such as, but not limited to, silicon, silicon-on-insulator (SOI), gallium arsenide and indium phosphide.

At least one continuity structure is integrally formed in the stacked configuration of metallization layers. The continuity structure may be disposed between the active circuits and a perimeter or edge of the stacked configuration, and electrically isolated from the active circuits. The continuity structure may intersect or traverse a plurality of metallization layers to form at least one continuous conductive path at least partially along the perimeter of the stacked configuration. For increased sensitivity edge damage, the continuity structure may be arranged along a substantial portion of the perimeter and in close proximity to the edges of the stacked configuration.

Accordingly, examples of appropriate continuity structures, include, but not limited to, a staircase structure, a series of two-step structures and other undulating structures.

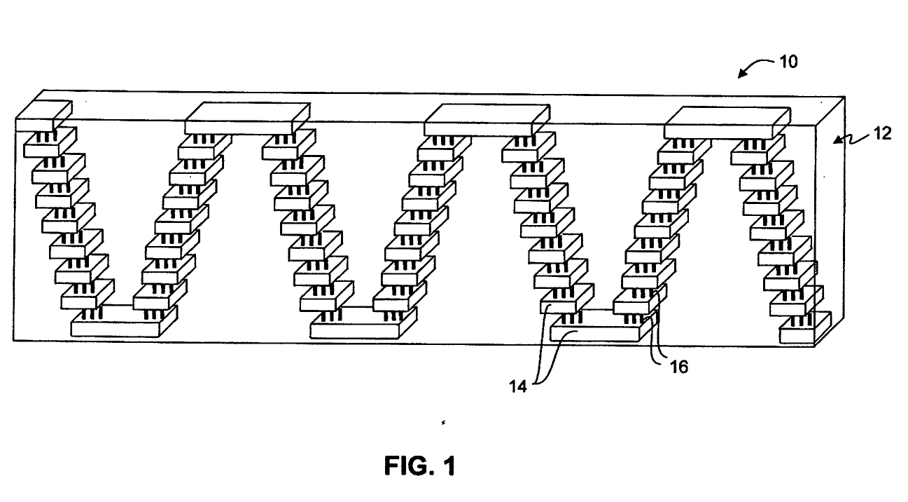

FIG. 1 illustrates a continuity structure 10 integrally formed in a stacked configuration of metallization layers 12 according to one embodiment. The continuity structure 10 comprises a plurality of discrete conductive lines 14 (substantially horizontal elements) disposed in each metallization layer in a staggered arrangement, and interconnects or vias 16 (substantially vertical elements) conductively coupling conductive lines 14 in adjacent metallization layers 12. One or more interconnects 16 may be provided at each interconnection portion between adjacent conductor lines 14. The continuity structure 10 may intersect a plurality of metallization layers 12, such as, in the form of a staircase arrangement. Conductive lines 14 of the continuity structure 10 may extend to the surface on the stacked configuration so that electrical tests may be performed between selected locations of the continuity structure 10 if required. For increased sensitivity to edge damage, the continuity structure 10 is disposed close to the perimeter 18 of the stacked metallization layers 12 and extends substantially along a perimeter 18 of the stacked configuration.

The continuity structure 10 of FIG. 1 may include nine layers which are integrally formed in an eight-layer stacked configuration or metal layers, with the topmost conductive lines of the continuity structure 10 disposed on the surface of the topmost metallization layer. Alternatively, the conductive lines 14 may be formed only in selected metallization layers that have been identified as being at a higher risk of propagating edge damage. While the conductive lines 14 are illustrated as having a rectangular shape, they may take on any other shapes, including, but not limited to, squares, ovals, circles and any customized shapes.

Variations to the embodiment of FIG. 1 may be made, including, but not limited to the following. Dimensions of the conductive lines 14 may be varied, subject to space availability between the active circuits and edge of the stacked configuration. The width of the conductive lines 14 and interconnects 16 can be any value allowed by manufacturing process, such as ranging between less than about 100 nm to more than about 10 μm. Gradient of the undulating continuity structure may be modified depending on the required sensitivity to edge damage. Further, a single interconnect may be provided to couple adjacent conductive lines.

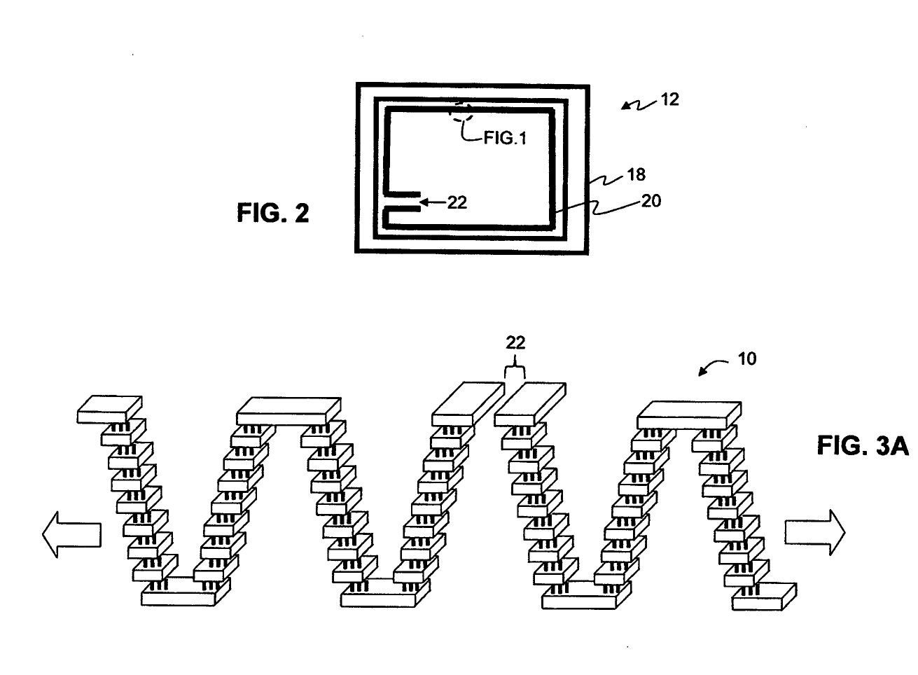

Reference is now made to FIG. 2 illustrating a schematic view of a conductive path 20 in a die of an IC chip or a substrate according to one embodiment. An exploded view of a portion of the conductive path 20 may be represented by FIG. 1. In FIG. 2, the conductive path 20 is provided substantially around the perimeter 18 of a die or substrate. The conductive path 20 may end at two terminals separated by a gap 22 there between. Dimensions of the gap 22 may range between less than about 0.1 μm to about 1 μm, but may be varied in other embodiments. It should be appreciated that dimensions of the gap 22 may be correlated to the perimeter 18, and is generally much smaller than the perimeter 18.

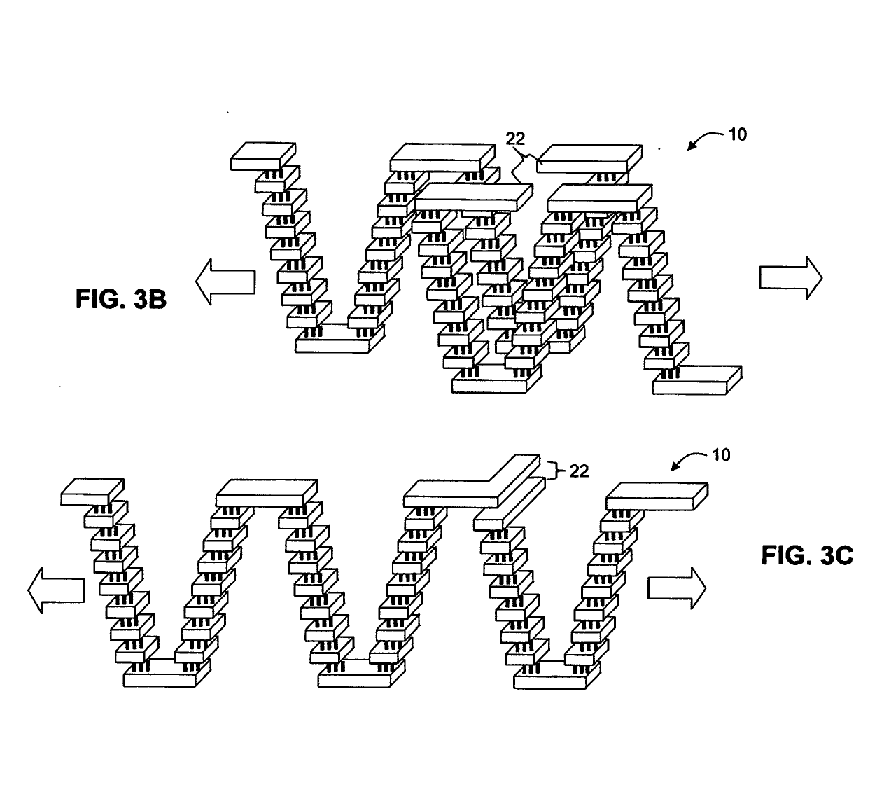

Terminals provided at both ends of the conductive path 20 are not restricted to the arrangement of FIG. 2. FIGS. 3A, 3B and 3C illustrate other possible arrangements of terminals in a continuity structure in various embodiments. Arrows in FIGS. 3A, 3B and 3C indicate cut-away sections of the continuity structures. FIGS. 3A and 3B illustrate continuity structures having terminals formed in the same metallization layer, whereas FIG. 3C illustrate a continuity structure having terminals arranged in adjacent metallization layers.

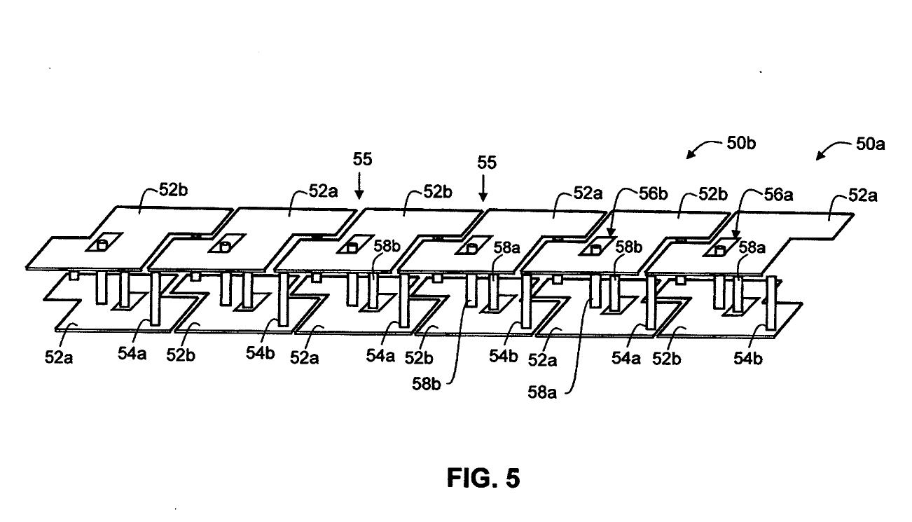

FIG. 5 is a perspective view of a plurality of continuity structures 50a, 50b according to one embodiment of the invention. Each continuity structure comprises a plurality of discrete conductive lines 52a, 52b (substantially horizontal elements) disposed in each metallization layer, and interconnects 54a, 54b (substantially vertical elements) conductively coupling adjacent conductive lines 52a, 52b of their respective structures 50a, 50b. The continuity structures 50a, 50b are arranged in close proximity and interweaved. However, the continuity structures 50a, 50b are separated by a small gap 55 to electrically isolate each other and to form separate conductive paths. The gap 55 separating the two continuity structures 50a, 50b may be configured at a minimally processable distance, such as about 100 nm for 65 nm technology nodes and may be further reduced for future technology nodes.

More specifically, a first continuity structure 50a may comprise a continuous series of two-step arrangements. Each two-step arrangement includes alternating discrete conductive lines 52a arranged in two metallization layers, where conductive lines 52a are coupled to one another by one or more interconnects 54a. A second continuity structure 50b may comprise a similar series of two-step arrangements in which the conductive lines 52b which may be vertically opposed to the conductive lines 52a of the first continuity structure 50a. Similarly, conductive lines 52b of the second continuity structure 50b are coupled to one another by one or more interconnects 54b. The width of the conductive lines and interconnects may range between less than about 100 nm to more than about 10 μm.

In addition, conductive lines 52a in the first continuity structure 50a may receive a part of the second continuity structure 50b in close proximity but electrically isolated from the first continuity structure 50a. An example includes having an aperture 56a in the conductive lines 52a of the first continuity structure 50a to receive a member 58b of the second continuity structure 50b. Similarly, the second continuity structure 50b may receive a member 58a of the first continuity structure 50a in close proximity but electrically isolated from each other. Such arrangement enhances sensitivity of the continuity structures to small local deformation and which results in an increased leakage between continuity structures 50a and 50b.

Variations to the embodiment of FIG. 5 may be made, including, but not limited to the following. Mulitple interconnects may be provided to electrically couple adjacent conductive lines of a continuity structure. Also, the conductive lines 52a, 52b may take the form of other shapes. In FIG. 5, the continuity structures 50a, 50b generally has the same height and their conductive lines 52a, 52b are arranged to intersect two metallization layers. Other embodiments, however, may provide continuity structures of same or different heights, which may be arranged to intersect three or more metallization layers.

Embodiments of the invention enable detection of edge damages in a speedy and cost-effective manner. Edge damages, including cracks and delamination, disrupt or displace the continuity structure to allow damage detection by monitoring changes to the continuity structure(s), such as by ascertaining certain electrical characteristics of the structure(s).

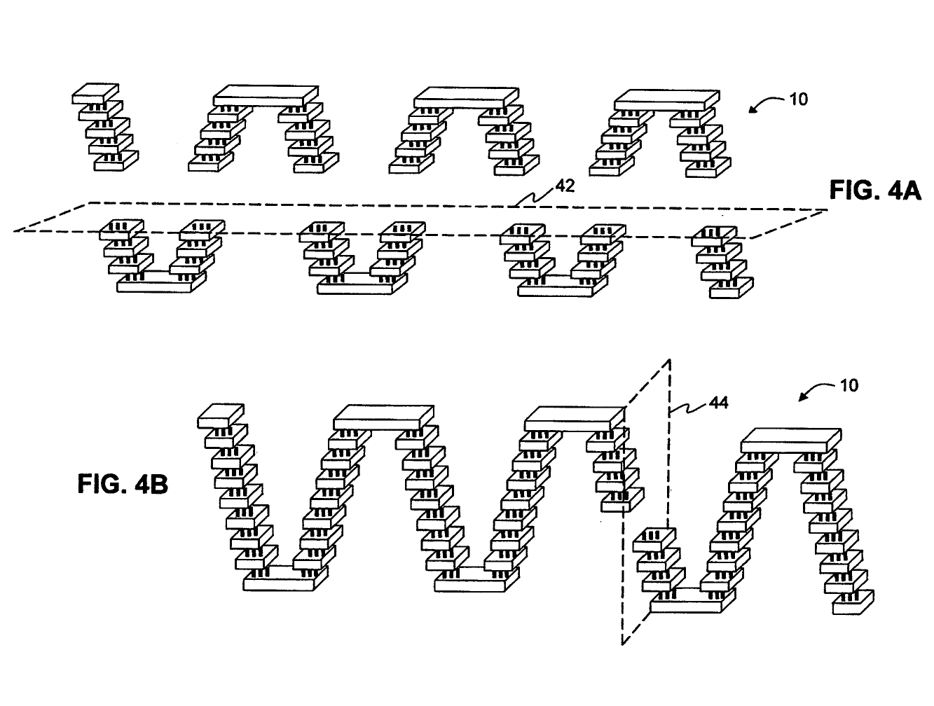

FIGS. 4A and 4B illustrate examples of disrupted continuity structures 10 based on the embodiment of FIG. 1 as a result of an edge damage. More specifically, FIG. 4A illustrates a severed continuity structure 10 as a result of a horizontal crack 42 (parallel to metallization layers). FIG. 4B illustrates a severed continuity structure 10 as a result of a vertical crack 44 (orthogonal to metallization layers). With the presence of edge damage, the embodiment of FIG. 1 experiences an overall increase in electrical resistance. If there is serious edge damage, the conductive path 20 may be open-circuited.

For the embodiment of FIG. 5, a presence of an edge damage may disrupt the continuity structures 50a, 50b to result in an open-circuit in at least one structure. As both continuity structures 50a, 50b are arranged in close proximity, edge damage may cause conductive lines 52a, 52b, members 58a, 58b, or both to come into electrical contact with each other and therefore resulting in a short-circuit.

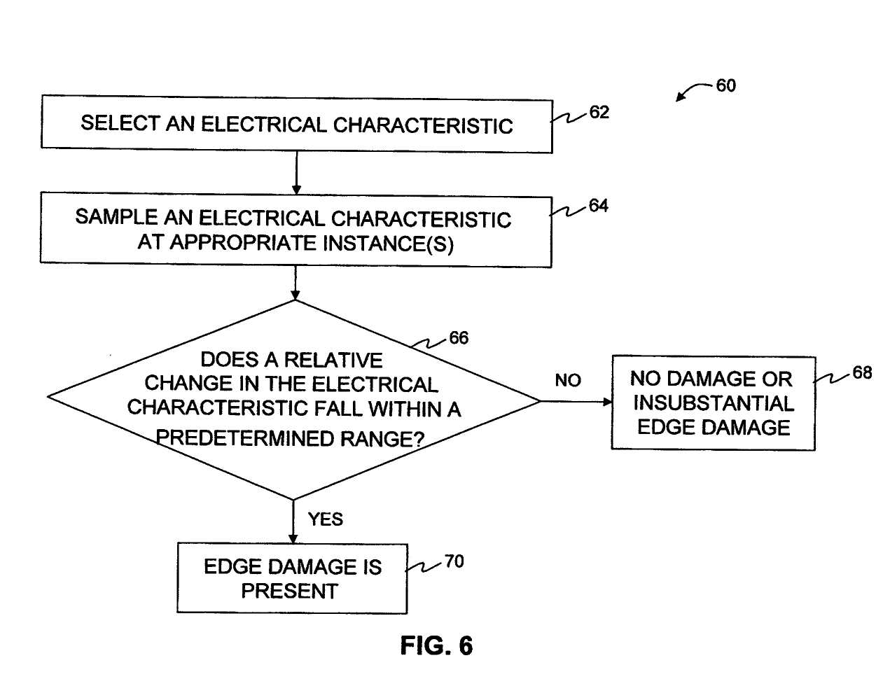

FIG. 6 is a flow sequence 60 of a method of detecting edge damage. An electrical characteristic, such as resistance, is first selected for monitoring a presence of edge damage in a block 62. At appropriate instance(s), the electrical characteristic of a conductive path or continuity structure is sampled in a block 64. It is then ascertained in a block 66 as to whether the conductive path undergoes a relative change in an electrical characteristic falling within a predetermined (anomalous) range and accordingly whether an edge damage is present.

Various methods for determining a relative change of the electrical characteristic include, but are not limited to the following. One method is by sampling the electrical characteristic of the conductive path or continuity structure both before and after a process to generate a plurality of values, and then ascertaining a relative change in the values. Alternatively, the electrical characteristic may be sampled only after a process to generate a first value which is compared against a predetermined value to ascertain a relative change. The predetermined value may be obtained and defined from data collected previously in similar processes.

If a relative change in the electrical characteristic does not fall within the predetermined (anomalous) range, it is determined in block 68 that there is no damage or that insubstantial damage is present. If the relative change in the electrical characteristic falls within the predetermined (anomalous) range, it is ascertained in block 70 that an edge damage is present. In defining the predetermined (anomalous) range, factors unrelated to edge damage, e.g., temperature changes and accuracy of equipment, may be accounted for.

Several illustrative detection methods are described as follows. A first method involves applying a voltage source between selected locations, e.g. terminals of a continuity structure, to ascertain an electrical resistance. Using Ohm's Law, (R=V/I, where R is resistance (ohms), V is voltage (Volts) and I is current (Amperes)), electrical resistance of the continuity structure is ascertained both before and after a manufacturing process, including, but not limited to dicing of a wafer into individual dies. Theoretically, both resistance readings should be substantially unchanged if there is no damage or is there is insubstantial edge damage. Practically, increases in resistance may be attributed to edge damage and/or other factors unrelated to edge damage. A relative increase in resistance due to factors unrelated to edge damage are relatively small, e.g., less than about 10%. A relative increase in resistance due to edge damage is, however, anomalous, e.g., more than about 10%, but not limited to this range. Accordingly, a relative increase in resistance may be indicative of a presence of edge damage and also of the extent of damage propagation.

A second method involves applying a current source between selected locations, e.g. terminals of a continuity structure. It should be appreciated from Ohm's law that a voltage increase is caused by an increase in resistance which in turn may be caused by edge damages. Similar to the first method, a small relative increase in voltage, e.g., less than about 10%, may be attributed to factors unrelated to edge damage while an anomalous relative increase, e.g., more than about 10%, may be attributed to edge damage.

For the embodiment of FIG. 5 having multiple conductive paths provided by multiple continuity structures, electrical resistance measurements of individual continuity structure as described above may be employed to detect a presence of edge damage. In addition, a third method is available in which a bias voltage may be applied between the first and the second structures 50a, 50b and a current leakage measured between the two structures. Current leakage may be a result of overlapping continuity structures coming into electrical contact. The overlapping may be caused by disruption or displacement of one or more continuity structures due to edge damage. If a relative change in the current leakage within a predetermined (anomalous) range, it is ascertained that an edge damage is present. For example, if a typical leakage at 1V of bias is in the range of nano Amperes, an increase in leakage current of more than 10 times is indicative of edge damage.

Embodiments of the invention may be formed by conventional techniques for forming vias and interconnects at the same time as forming the metallization layers. For example, holes may be formed in each metallization layer by etching, laser drilling or other known methods. The holes may be filled or plated with a conductive material to form the conductive lines and interconnects. Examples of a conductive material include, but not limited to, copper and aluminium.

Embodiments of the present invention may also be applied to a variety of front-end applications involving a semiconductor material, including, but not limited to silicon, silicon-on-insulator (SOI), gallium arsenide and indium phosphide. Embodiments of the present invention may be applied to a variety of back-end applications involving a packaging substrate comprising a material, including, but not limited to silicon dioxide with all its low-k variants, low-k material, ceramic, glass and any combination thereof.

Other embodiments will be apparent to those skilled in the art from consideration of the specification and practice of the present invention. Furthermore, certain terminology has been used for the purposes of descriptive clarity, and not to limit the invention. The embodiments and features described above should be considered exemplary, with the invention being defined by the appended claims.

What is claimed is:

1. A structure comprising:
a plurality of metallization layers arranged in a stacked configuration;
a plurality of circuits formed in the plurality of metallization layers; and
a first conductive path intersecting the plurality of metallization layers and disposed between the plurality of circuits and a perimeter of the stacked configuration to detect a damage in the stacked configuration.

2. The structure of claim 1, wherein the first conductive path is an undulating structure.

3. The structure of claim 2, wherein the undulating structure comprises:
a plurality of conductive lines formed in the plurality of metallization layers; and
an interconnect conductively coupling the plurality of conductive lines in adjacent metallization layers.

4. The structure of claim 1, wherein the first conductive path is to undergo a predetermined relative change in an electrical characteristic when the damage is present in the stacked configuration.

5. The structure of claim 1, wherein the first conductive path extends substantially along the perimeter of the stacked configuration.

6. The structure of claim 5, wherein the first conductive path includes two terminals which are separated from each other by between about 0.1 μm to about 1 μm.

7. The structure of claim 1, further comprising a second conductive path intersecting the plurality of metallization layers, wherein the first and the second conductive paths are electrically isolated from each other.

8. The structure of claim 7, wherein the first and the second conductive paths are to come into electrical contact when the damage is present in the stacked configuration.

9. The structure of claim 7, wherein the first conductive path is a first structure and the second conductive path is a second structure, wherein the first structure and the second structure are separated by a gap of between about 40 nm to about 60 nm.

10. The structure of claim 9, wherein the first and the second structures are disposed in an interweaved arrangement.

11. A method of detecting damage, comprising:
providing a semiconductor device having a plurality of metallization layers arranged in a stacked configuration;
forming a plurality of circuits in the plurality of metallization layers;
forming a conductive path intersecting the plurality of metallization layers, the conductive path being disposed between the plurality of circuits and a perimeter of the stacked configuration;
applying an electrical source to the conductive path; and
determining a relative change in an electrical characteristic of the conductive path to ascertain whether or not a damage is present in the stacked configuration.

12. The method of claim 11, wherein determining a relative change in an electrical characteristic further comprising:
sampling the electrical characteristic to generate a plurality of values; and
ascertaining the relative change in the electrical characteristic from the plurality of values.

13. The method of claim 11, wherein determining a relative change in an electrical characteristic further comprising:
defining a predetermined value of the electrical characteristic;
sampling the electrical characteristic to generate a first value; and
ascertaining the relative change based on the predetermined value and the first value.

14. The method of claim 11, wherein the electrical characteristic is an electrical resistance of the conductive path.

15. A method of detecting damage, comprising:
providing a semiconductor device having a plurality of metallization layers arranged in a stacked configuration;
forming a plurality of circuits in the plurality of metallization layers;
forming a first conductive path and a second conductive path intersecting the plurality of metallization layers, the first and the second conductive paths being electrically isolated from each other and disposed between the plurality of circuits and a perimeter of the stacked configuration;
applying an electrical source to the first and the second conductive paths; and
determining a relative change in an electrical characteristic to ascertain whether or not a damage is present in the stacked configuration.

16. The method of claim 15, wherein the electrical characteristic is current leakage between the first and the second conductive paths.

17. The method of claim 15, wherein determining a relative change in an electrical characteristic further comprising:
defining a predetermined value of the electrical characteristic;
sampling the electrical characteristic of one of the first and the second conductive paths to generate a first value; and
ascertaining the relative change based on the predetermined value and the first value.
